(19) United States
(12) Patent Application Publication
(10) Pub. No.: US 2005/0205938 A1
(43) Pub. Date: Sep. 22, 2005

(54) Semiconductor device and method of manufacture the same

(76) Inventor: Atsushi Yagishita, Yokohama-shi (JP)

Correspondence Address: Finnegan, Henderson, Farabow,;Garrett & Dunner, L.L.P., 1300 I Street, N.W., Washington, DC, 20005-3315, US

(21) Appl. No.: 11/028,635

(22) Filed: Jan. 5, 2005

(30) Foreign Application Priority Data
Jan. 7, 2004 (JP) 2004-002228

(51) Int. Cl. H01L 29/76

(52) U.S. Cl. 257/369

(57) ABSTRACT

A semiconductor device comprises a p-type semiconductor region provided in a semiconductor substrate, an n-type semiconductor region provided in the semiconductor substrate and being in contact with the p-type semiconductor region, an n-type source region and an n-type drain region between which the p-type semiconductor region is sandwiched, a p-type source region and a p-type drain region between which the n-type semiconductor region is sandwiched, a gate insulating film formed on the p-type semiconductor region and the n-type semiconductor region, and a gate electrode formed on the gate insulating film and electrically connected to the p-type semiconductor region and the n-type semiconductor region.

### CROSS-REFERENCE TO RELATED APPLICATIONS

This application is based upon and claims the benefit of priority from prior Japanese Patent Application No. 2004-002228, filed Jan. 7, 2004, the entire contents of which are incorporated herein by reference.

### BACKGROUND OF THE INVENTION

1. Field of the Invention

The present invention relates a semiconductor device and a method of manufacture the same.

2. Description of the Related Art

To reduce power consumption of MIS-LSIs (MOS-LSIs), the supply voltage Vdd has been increasingly lowered. To prevent off current from increasing, however, the threshold voltage Vth of MISFETs has not been lowered munch. For this reason, transistors tend to lower their drivability Id. To overcome this problem, a dynamic threshold-voltage MISFET (DTMISFET) has been proposed (see, for example, “Fariborz Assaderaghi, et al, “Dynamic threshold-voltage MOSFET (DTMOS) for Ultra-Low voltage VLSI”, IEEE Trans, Electron Devices, vol. 44, pp. 414-421, 1997”).

The DTMISFET is a MISFET in which the gate and the well (the Si body in the case of an SOI substrate) are electrically connected together and has merits that the drivability is large even if the supply voltage Vdd is small and that the off current is small. This is explained by the operating principles characteristic of the DTMISFET that the substrate bias effect is produced by applying a gate voltage to the substrate and as a result the threshold voltage Vth becomes low when the transistor is on and the threshold voltage Vth becomes high when the transistor is off.

Let us consider using a DT-nMISFET and a DT-pMISFET to form an inverter. To form one inverter, two wells (an n-type well and a p-type well) are required. To electrically connect the gate electrode and each well, therefore, two contacts must be formed, resulting in a problem that the layout area increases. In addition, there is also a problem that the layout area of an isolation region for isolating the p-type well and the n-type well from each other will increase.

Thus, with DT-CMISFETs (DT-CMOSFETs), there is a problem that the layout area increases.

### BRIEF SUMMARY OF THE INVENTION

According to a first aspect of the present invention, there is provided a semiconductor device comprising: a p-type semiconductor region provided in a semiconductor substrate; an n-type semiconductor region provided in the semiconductor substrate and being in contact with the p-type semiconductor region; an n-type source region and an n-type drain region between which the p-type semiconductor region is sandwiched; a p-type source region and a p-type drain region between which the n-type semiconductor region is sandwiched; a gate insulating film formed on the p-type semiconductor region and the n-type semiconductor region; and a gate electrode formed on the gate insulating film and electrically connected to the p-type semiconductor region and the n-type semiconductor region.

According to a second aspect of the present invention, there is provided a method of manufacturing a semiconductor device comprising: forming a p-type well and an n-type well in a semiconductor substrate which are in contact with each other; forming a dummy gate on the p-type well and the n-type well except a boundary portion of the p-type well and the n-type well; introducing n-type impurities into the p-type well using the dummy gate as a mask to form an n-type source region and an n-type drain region in the p-type well; introducing p-type impurities into the n-type well using the dummy gate as a mask to form a p-type source region and a p-type drain region in the n-type well; forming a first insulating film which surrounds the dummy gate; forming a trench in the first insulating film by removing the dummy gate; forming a gate insulating film in the trench; removing the first insulating film on the boundary portion to expose a surface of the boundary portion; and forming a gate electrode on the gate insulating film in the trench and on the exposed surface of the boundary portion.

According to a third aspect of the present invention, there is provided a method of manufacturing a semiconductor device comprising: forming a p-type well and an n-type well in a semiconductor substrate which are in contact with each other; forming a gate insulating film on the p-type well and the n-type well; forming a lower portion of a gate electrode on the gate insulating film except a boundary portion of the p-type well and the n-type well; introducing n-type impurities into the p-type well using the lower portion of the gate electrode as a mask to form an n-type source region and an n-type drain region in the p-type well; introducing p-type impurities into the n-type well using the lower portion of the gate electrode as a mask to form a p-type source region and a p-type drain region in the n-type well; and forming an upper portion of the gate electrode on the lower portion of the gate electrode and on a surface of the boundary portion.

### BRIEF DESCRIPTION OF THE SEVERAL VIEWS OF THE DRAWING

FIGS. 1A and 1B show the basic structure of a semiconductor device according to an embodiment of the present invention;

FIG. 2 shows the equivalent circuit of an inverter using DT-CMISFETs;

FIGS. 3A and 3B show the structure of a semiconductor device according to a first embodiment of the present invention;

FIGS. 4A, 4B and 4C through FIGS. 10A, 10B and 10C show the process of manufacturing the semiconductor device according to the first embodiment of the present invention;

FIGS. 11A and 11B show the structure of a semiconductor device according to a second embodiment of the present invention;

FIGS. 12, 12B and 12C through FIGS. 14A, 14B and 14C show the process of manufacturing the semiconductor device according to the second embodiment of the present invention.

### DETAILED DESCRIPTION OF THE INVENTION

The embodiments of the present invention will be described hereinafter with reference to the accompanying drawings.

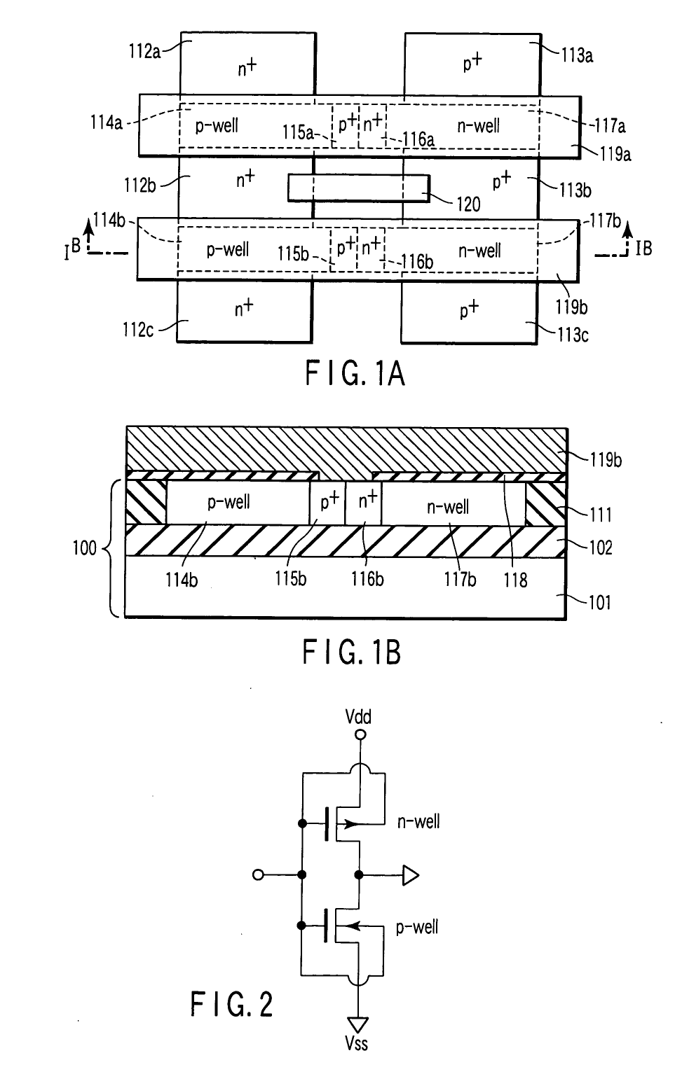

FIGS. 1A and 1B show the basic structure of a semiconductor device according to an embodiment of the present invention. FIG. 1A is a plan view and FIG. 1B is a sectional view taken along line IB-IB of FIG. 1A. In the semiconductor device shown in FIGS. 1A and 1B, two inverters using DT-CMISFETs are formed.

As shown in FIGS. 1A and 1B, the semiconductor device of this embodiment uses, as its semiconductor substrate, an SOI (silicon on insulator) substrate 100 in which an Si support substrate 101, a buried oxide film 102 and an Si semiconductor layer are stacked.

An isolation insulating film 111 which surrounds a device region is formed on the buried oxide film 102. In addition, the buried oxide film 102 is formed on top with n⁺-type source/drain regions 112 (112a, 112b, and 112c), p⁺-type source/drain regions 113 (113a, 113b, and 113c), p-type semiconductor portions 114 (114a and 114b), n-type semiconductor portions 117 (117a and 117b), p⁺-type semiconductor portions (p⁺ diffusion layers) 115 (115a and 115b), and n⁺-type semiconductor portions (n⁺ diffusion layers) 116 (116a and 116b). The n⁺-type source/drain regions 112, the p⁺-type source/drain regions 113, the p-type semiconductor portions 114, the n-type semiconductor portions 117, the p⁺-type semiconductor portions 115 and n⁺-type semiconductor portions 116 are formed in the Si semiconductor layer of the SOI substrate 100. The p-type semiconductor regions including the p-type semiconductor portions 114 and the p⁺-type semiconductor portions (p⁺ diffusion layers) 115 are formed in a p-type well and the n-type semiconductor regions including the n-type semiconductor portions 117 and the n⁺-type semiconductor portions (n⁺ diffusion layers) 116 are formed in an n-type well.

The n⁺-type source/drain region 112 and the p-type semiconductor portion 114 are formed alternately along a predetermined direction. The p⁺-type source/drain region 113 and the n-type semiconductor portion 117 are also formed alternately along the predetermined direction. The p-type semiconductor portion 114, the p⁺-type semiconductor portion 115, the n⁺-type semiconductor portion 116 and the n-type semiconductor portion 117 are arranged successively in a direction perpendicular to that predetermined direction.

The p-type semiconductor portions 114 and the n-type semiconductor portions 117 are formed on top with a gate insulating film 118. The gate insulating film 118, the p⁺ diffusion layers 115 and the n⁺ diffusion layers 116 are formed on top with metal gate electrodes 119 (119a and 119b). The gate electrodes 119 are directly formed on the p⁺ diffusion layers 115 and the n⁺ diffusion layers 116. A contact interconnection (connecting portion) 120 is formed to electrically connect one of the n⁺-type source/drain regions 112 to one of the p⁺-type source/drain regions 113.

As described above, with the semiconductor device (DT-CMISFET inverter) of this embodiment, the p⁺-type semiconductor portion (p⁺ diffusion layer) 115 and the n⁺-type semiconductor portion (n⁺ diffusion layer) 116 are in direct contact with each other. That is, a pn junction is formed by the p-type semiconductor region for DT-nMISFET and the n-type semiconductor region for DT-pMISFET. Therefore, no isolation region is formed between the p-type semiconductor region and the n-type semiconductor region.

In addition, no gate insulating film is formed on the pn junction portion of the p⁺-type semiconductor portion 115 and the n⁺-type semiconductor portion 116, that is, on the boundary portion of the p⁺-type semiconductor portion 115 and the n⁺-type semiconductor portion 116. A portion of the metal gate electrode 119 is formed on that boundary portion. That is, the p-type semiconductor region for DT-nMISFET and the n-type semiconductor region for DT-pMISFET are electrically connected together by the gate electrode 119.

The reason why there is no need to form an isolation region between the p-type semiconductor region and the n-type semiconductor region will be described with reference to FIG. 2, which shows the equivalent circuit of an inverter using DT-CMISFETs.

As shown in FIG. 2, with DT-CMISFETs, the gate electrode, the n-type well (the n-type semiconductor region in this embodiment) and the p-type well (the p-type semiconductor region in this embodiment) are electrically connected. That is, the n-type well and the p-type well in the inverter are electrically connected by the common gate electrode. More generally speaking, wells of DT-MISFETs connected to a common gate interconnection are electrically connected by the gate interconnection. Therefore, there is no need to form an isolation region between such wells.

As described above, according to this embodiment, a pn junction is formed by the p⁺-type semiconductor portion 115 and the n⁺-type semiconductor portion 116, causing the p-type semiconductor region and the n-type semiconductor region to come into direct contact with each other. Therefore, since no isolation region is formed between the p-type semiconductor region and the n-type semiconductor region, the circuit layout area can be reduced. In addition, if the layout area is set equal to the conventional one, the distance between the p⁺-type and n⁺-type semiconductor portions for gate electrode connection and the p⁺-type and n⁺-type source/drain regions can be increased. This allows the alignment margin in lithography to be increased.

In addition, contact to the gate electrode is made at the pn junction between the p⁺-type semiconductor portion 115 and the n⁺-type semiconductor portion 116, i.e., at the boundary portion between the p⁺-type semiconductor portion 115 and the n⁺-type semiconductor portion 116. Therefore, the number of contacts can be reduced from two to one, allowing the circuit layout area to be reduced. Moreover, if the layout area is set equal to the conventional one, the contact can be made large in size, thus, allowing the contact pattern forming process by lithography or etching to be made easy.

### Embodiment 1

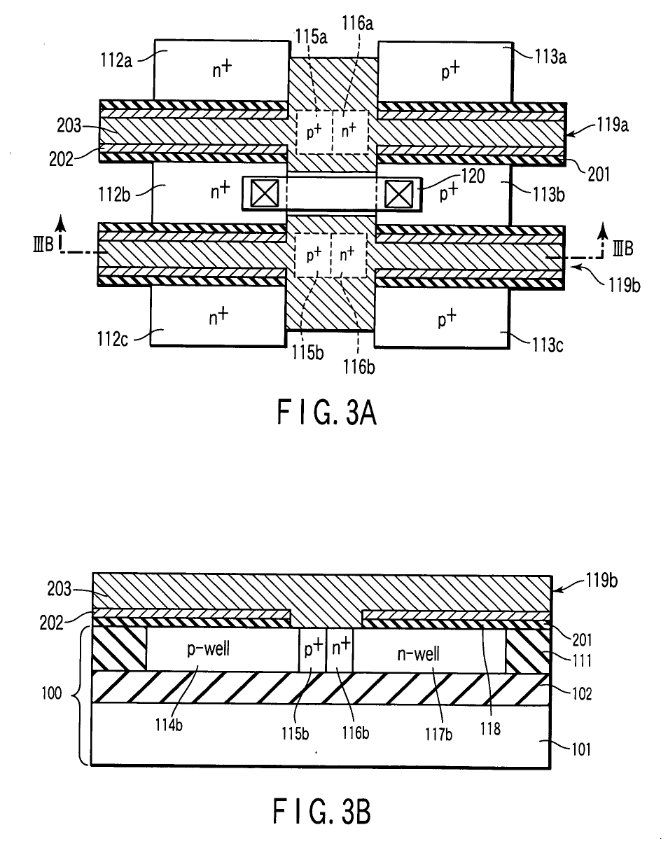

FIGS. 3A and 3B shows the structure of a semiconductor device according to a first embodiment of the present invention. FIG. 3A is a plan view and FIG. 3B is a sectional view taken along line IIIB-IIIB of FIG. 3A. In FIGS. 3A and 3B, corresponding constituents to those in FIGS. 1A and 1B are denoted by like reference numerals and detailed descriptions thereof are omitted.

In this embodiment, a ZrO₂ film, which is a high dielectric constant film, is used as the gate insulating film. As the gate electrode, use is made of a metal gate electrode in which a TiN film 202 and an Al film 203 are stacked.

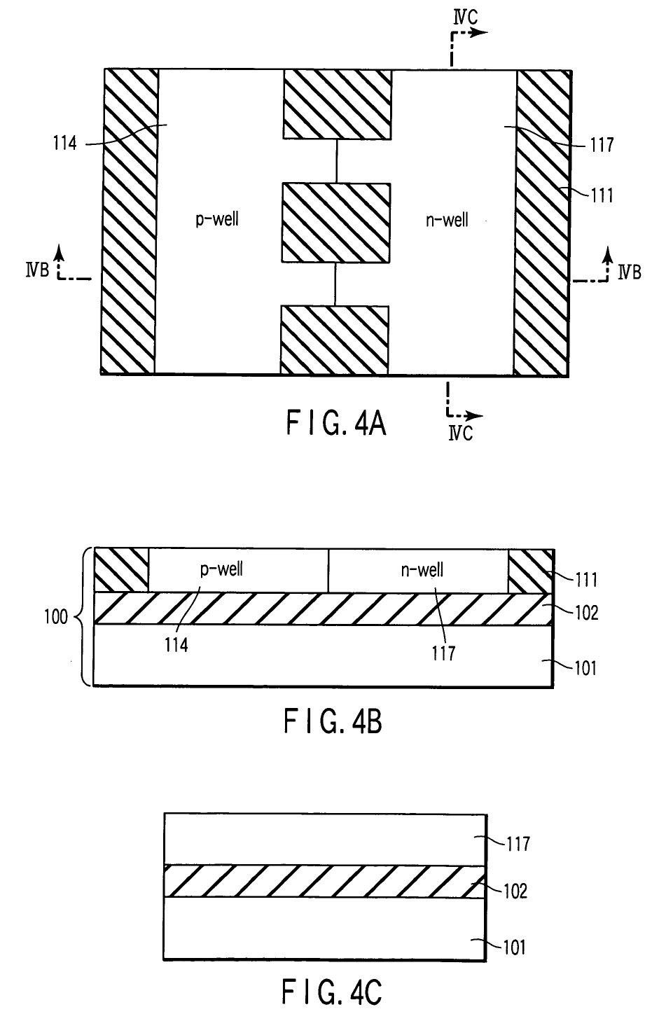

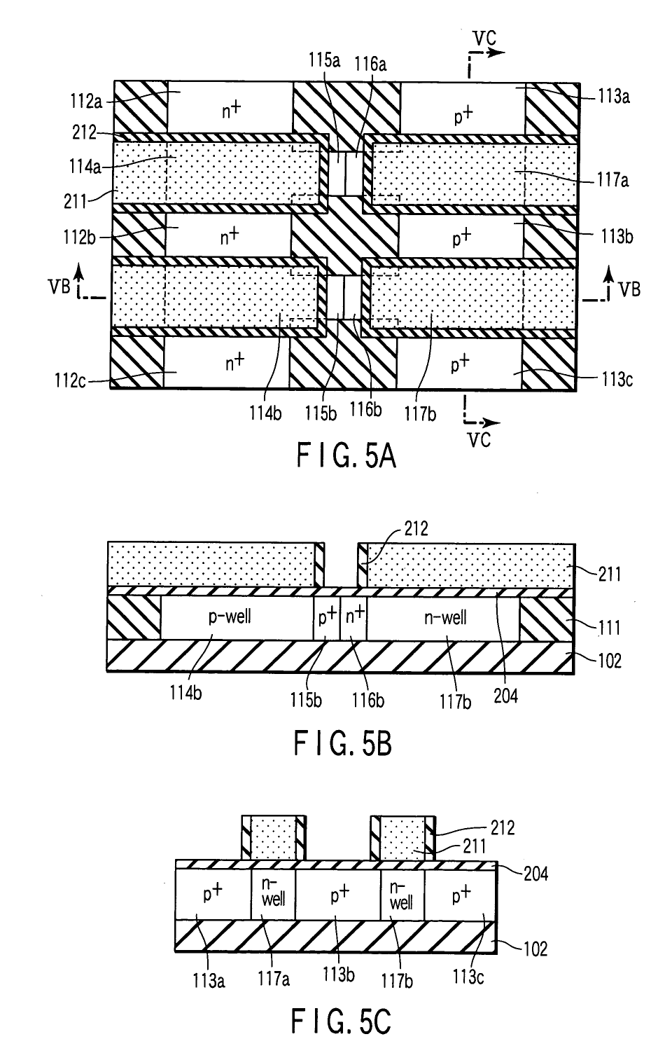

Reference is now made to FIGS. 4A, 4B and 4C through FIGS. 10A, 10B and 10C to describe the process of manufacturing the semiconductor device according to this embodiment. Note that, in FIGS. 5A, 5B and 5C through FIGS. 10A, 10B and 10C, the Si support substrate 101 in the SOI substrate 100 is omitted.

First, as shown in FIGS. 4A, 4B and 4C, an SOI substrate 100 is prepared in which the thickness of an Si thin layer on a buried oxide film 102 is of the order of 100 nm. Subsequently, an isolation insulating film 111 the thickness of which is of the order of 100 nm is formed by means of STI techniques. This isolation insulating film 111 is formed in regions other than pMISFET and nMISFET formation regions.

After that, an n-type well 117 and a p-type well 114 are formed in a DT-pMISFET formation region and a DT-nMISFET formation region, respectively, in the Si thin layer. In the drawing, a pn junction is formed by the p-type well 114 and the n-type well 117 in two places. A portion of a gate electrode is formed on the pn junction portion at a later time.

Next, as shown in FIGS. 5A, 5B and 5C, a thermal oxide film 204 which is of the order of 5 nm in thickness is formed on the surface of the n-type well 117 and the p-type well 114. Subsequently, a poly-Si film 211 which is of the order of 150 nm in thickness is deposited on the thermal oxide film 204 by LPCVD. This poly-Si film 211 is used in subsequent steps as an ion implantation mask and a CMP stopper.

Subsequently, a resist pattern (not shown) is formed. Using this resist pattern as a mask, the poly-Si film 211 is etched by RIE to form dummy gates 211. At this time, the poly-Si film 211 is patterned so that the dummy gate 211 is not formed on the pn junction portion (boundary portion) between the p-type well 114 and the n-type well 117.

After the removal of the resist pattern, using the dummy gates 211 as a mask, p-type impurities and n-type impurities are ion implanted into the DT-pMISFET formation region and the DT-nMISFET formation region, respectively. Thereby, though not shown, shallow p-type and n-type impurity diffusion layers (extension regions) are formed. A resist pattern is formed as a mask in regions into which the impurity ions are not implanted.

Next, a silicon nitride film (Si₃N₄ film) is formed at a thickness of the order of 30 nm. Further, sidewall portions 212 are formed on the sidewalls of the dummy gates 211 by etching the Si₃N₄ film by means of RIE. Subsequently, p-type impurities and n-type impurities are ion implanted into the n-type well 117 and the p-type well 114, respectively. At this time, not only the resist pattern but also the dummy gates 211 and the sidewall portions 212 are used as a mask.

By the step of ion implantation of the n-type impurities, n⁺-type source/drain regions 112 (112a, 112b, and 112c) are formed in the p-type well 114. In this ion implantation step, at the same time, the n-type impurities are also ion implanted into end portions (boundary portions between the p-type well 114 and the n-type well 117) of the n-type well 117 to form n⁺ diffusion layers (n⁺-type semiconductor portions) 116 (116a and 116b). Also, p⁺-type source/drain regions 113 (113a, 113b, and 113c) are formed in the n-type well 117 by the step of ion implantation of the p-type impurities. In this ion implantation step, at the same time, the p-type impurities are also ion implanted into end portions (boundary portions between the p-type well 114 and the n-type well 117) of the p-type well 114 to form p⁺ diffusion layers (p⁺-type semiconductor portions) 115 (115a and 115b). The order in which the p-type impurity ion implantation step and the n-type impurity ion implantation step are performed is not particularly restricted. Further, the implanted impurities are activated at a temperature of the order of 1000° C. The p⁺ diffusion layers 115 and the n⁺ diffusion layers 116 are used as contacts to the gate electrodes.

Thus, the n⁺-type source/drain regions 112 and the n⁺ diffusion layers 116 are formed at the same time by the n-type impurity ion implantation step. Also, the p⁺-type source/drain regions 113 and the p⁺ diffusion layers 115 are formed at the same time by the p-type impurity ion implantation step. Therefore, the number of ion implantation steps can be reduced, allowing the manufacturing process to be simplified.

The exemplary ion implantation conditions in forming the n-type extension regions are such that the impurity ions are As ions, the accelerating voltage is 15 keV, and the dose is 3×10¹⁴ cm⁻². The exemplary ion implantation conditions in forming the n⁺-type source/drain regions are such that the impurity ions are As ions, the accelerating voltage is 45 keV, and the dose is 3×10¹⁵ cm⁻².

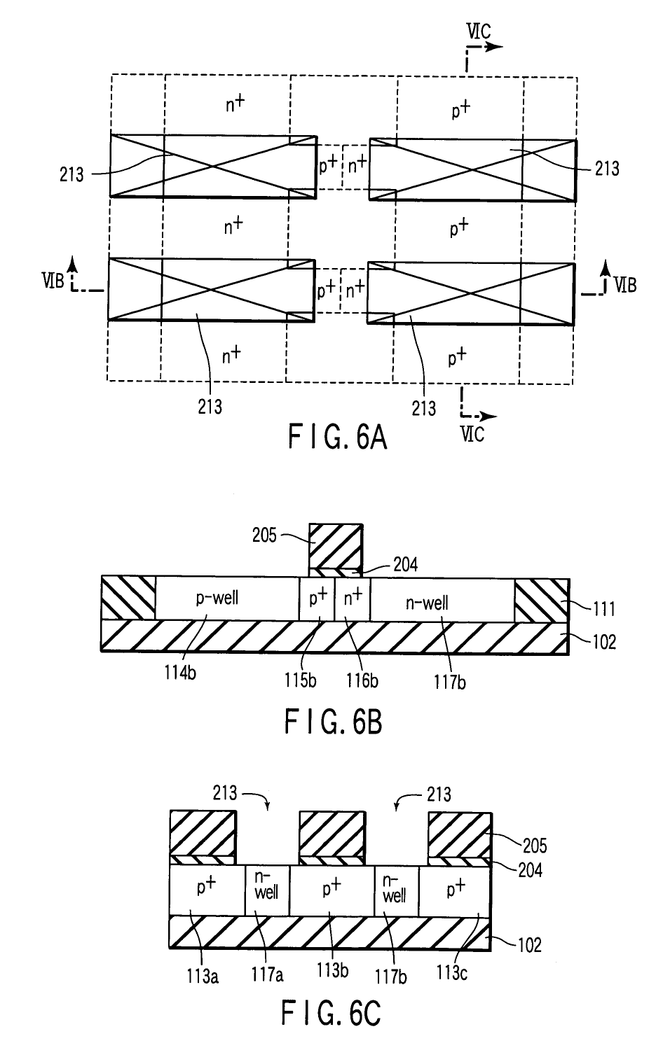

Next, as shown in FIGS. 6A, 6B and 6C, a TEOS-SiO₂ film 205 is deposited over the entire surface. Subsequently, the surface of the TEOS-SiO₂ film 205 is planarized by CMP to expose the top of the dummy gates 211. Next, the dummy gates 211 are removed by CDE or the like to form gate trenches 213 in regions where gate electrodes are to be formed. Further, the thermal oxide film 204 at the bottom of the gate trenches 213 is removed by means of HF-based wet etching to expose the surface of the p-type well 114 and the n-type well 117.

Next, a gate insulating film is formed. Since the sources/drains have been already formed, it is not desirable to perform a heat treatment process at high temperatures in excess of 600° C. Thus, a high dielectric constant film or a ferroelectric film, such as an HfO₂ film, a ZrO₂ film, a Ta₂O₅ film, a TiO₂ film, a (Ba, Sr)TiO₃ film, is used as the gate insulating film. A metallic conductive material is used for the gate electrode. When a high dielectric constant film or ferroelectric film is used as the gate insulating film, it is required to select a gate electrode material according to the gate insulating film used. For example, Al, W, Ru, Mo, TiN, TaN, WN, and so on can be used. In the example given here, a ZrO₂ film is used as the high-k gate insulating film and stacked Al/TiN film is used as the gate electrode.

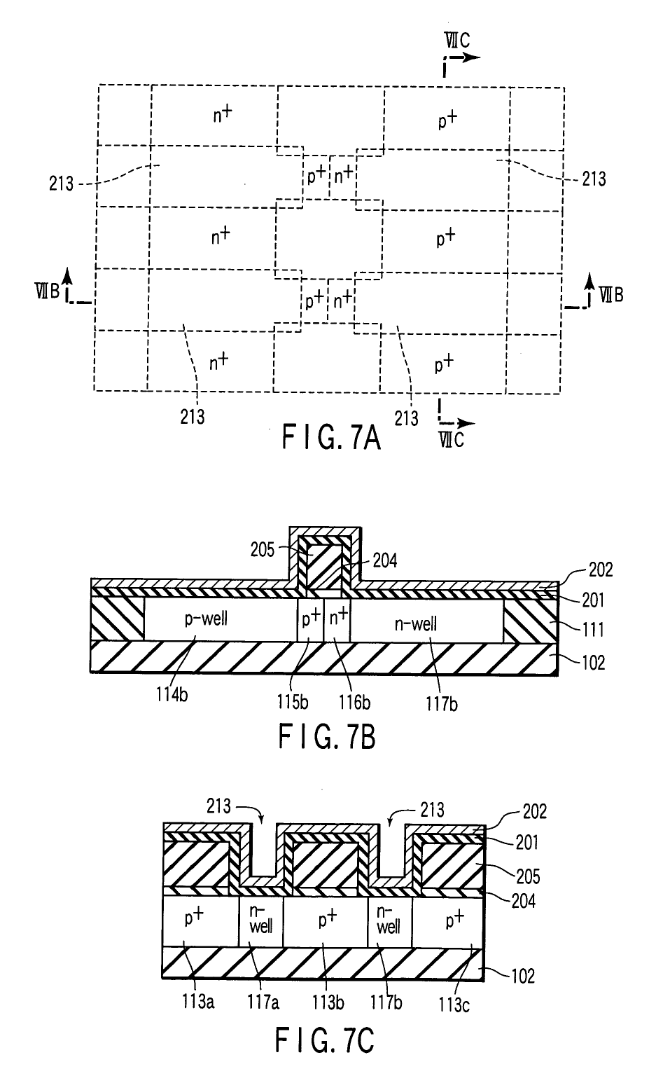

As shown in FIGS. 7A, 7B and 7C, a gate insulating film 201 which is of the order of 3 nm in thickness is deposited after the surface of the p-type well 114 and the n-type well 117 exposed at the bottom of the gate trenches 213 has been nitrided thin. A TiN film 202 of 5 nm in thickness is deposited as the first-level metal gate electrode film on the gate insulating film 201 by means of CVD.

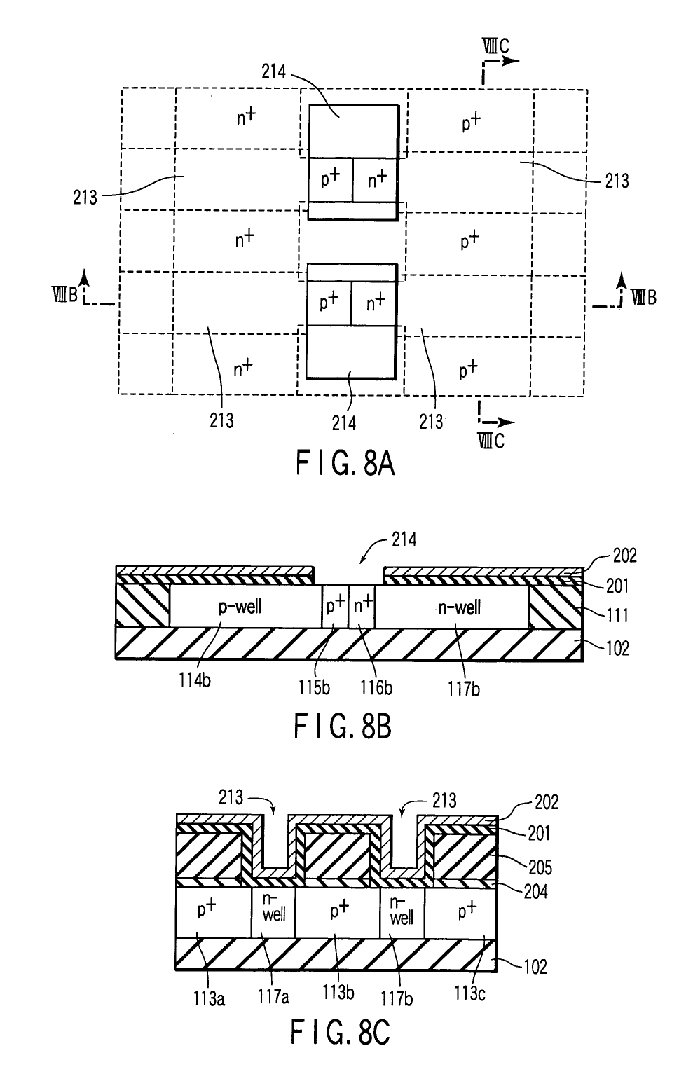

Next, as shown in FIGS. 8A, 8B and 8C, a resist pattern not shown is formed on the TiN film 202. This resist pattern is formed with a pattern of openings over the p⁺ diffusion layers 115 and the n⁺ diffusion layers 116. Using this resist pattern as a mask, the TiN film 202, the gate insulating film (ZrO₂ film) 201, the TEOS-SiO₂ film 205 and the thermal oxide film 204 are removed by RIE to form contact holes 214. At the bottoms of the contact holes, the surface of the p⁺ diffusion layers 115 and the n⁺ diffusion layers 116 is exposed.

The above resist pattern is formed, not onto the gate insulating film 201, but onto the TiN film 202. The direct formation of the resist pattern onto the gate insulating film results in a degradation in the reliability of the gate insulating film. In this embodiment, since the resist pattern is not directly formed on the gate insulating film 201 but on the TiN film 202, the reliability of the gate insulating film improves.

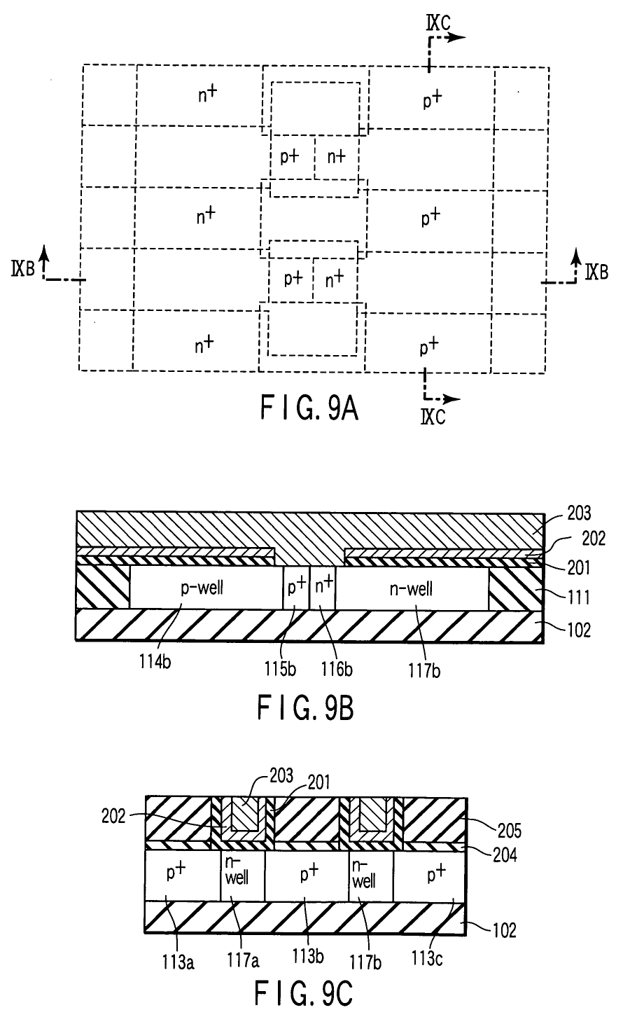

As shown in FIGS. 9A, 9B and 9C, after the removal of the resist pattern, an Al film 203 is deposited to a thickness of about 300 nm as the second-level metal gate electrode film. Subsequently, the surface of the Al film 203 is planarized to form stacked-structure metal gate electrodes formed from the TiN film 202 and the Al film 203.

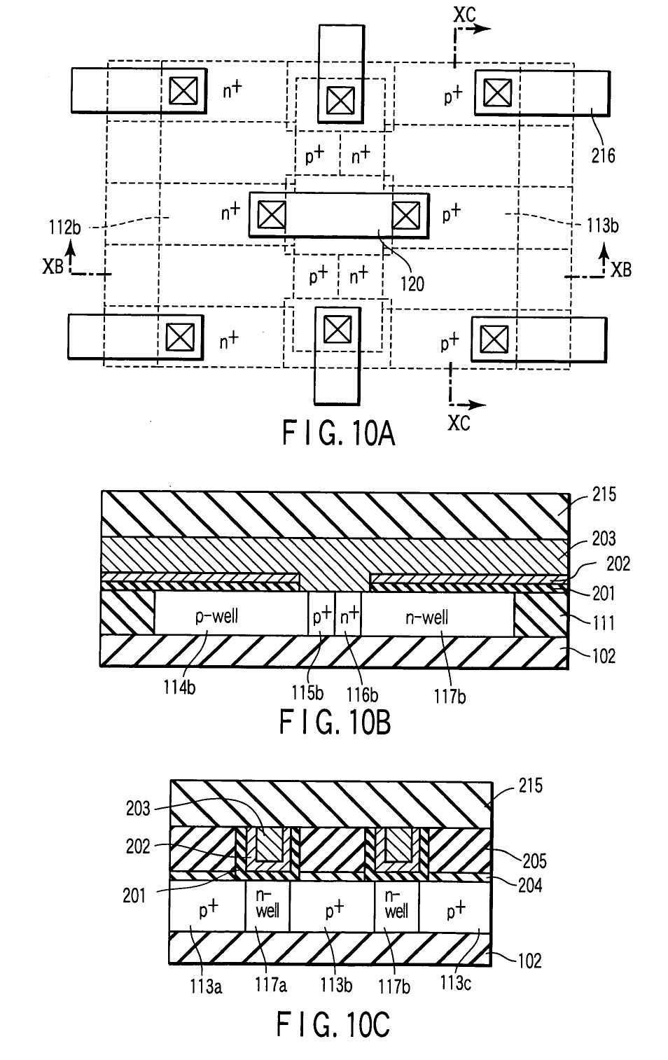

The subsequent process remains unchanged from the usual LSI manufacturing process. As shown in FIGS. 10A, 10B and 10C, an interlayer insulating film 215 of TEOS-SiO₂ is deposited by means of CVD. Subsequently, contact holes are formed in the interlayer insulating film 215 over the source/drain regions and the gate electrodes. Metal interconnections (for example, Al wirings) 216 are formed in the contact holes and on the interlayer insulating film 215. At this time, a contact interconnection (connecting portion) 120 is also formed to electrically connect the n⁺ source/drain region 112b of the nMISFET and the p⁺ source/drain region 113b of the pMISFET. Thus, a CMISFET inverter is formed.

According to this embodiment, as described above, since the p-type semiconductor region and the n-type semiconductor region are in direct contact with each other with no isolation region formed therebetween, the circuit layout area can be reduced. In addition, since contact to the gate electrode is made at the boundary portion of the p-type semiconductor region and the n-type semiconductor region, the number of contacts can be reduced and the circuit layout area can be reduced. Moreover, if the layout area is set equal to the conventional area, the lithography process and the pattern forming process will become easy.

Furthermore, the n-type impurity ion implantation process allows the n⁺-type source/drain regions and the n⁺ diffusion layers at contact portions to be formed at the same time. Likewise, the p-type impurity ion implantation process allows the p⁺-type source/drain regions and the p⁺ diffusion layers at contact portions to be formed at the same time. Therefore, the number of ion implantation steps can be reduced, allowing the manufacturing process to be simplified.

In addition, since the gate electrode is formed of a metallic conductive material, electrical connection to both the p-type semiconductor region and the n-type semiconductor region can be made with ease, allowing CMISFETs to be formed easily. Also, since it is not required to form a resist pattern directly on the gate insulating film in forming contact holes for gate electrode connection, the reliability of the gate insulating film increases.

Moreover, the optimization of the channel-region profile will make a low threshold voltage Vth (about 0.2V) feasible, which is said to be unfeasible with MISFETs using mid-gap work function metal gates.

Furthermore, when an SOI substrate is used, wells are automatically isolated from each other by a buried oxide film (BOX-SO₂), thus allowing the formation area of the isolation insulating film to be further reduced. That is, with DTMISFETs, it is generally required to electrically isolate individual transistors. When a bulk Si substrate is used, neighboring wells are short-circuited; thus, sources/drains cannot be shared. The use of an SOI substrate allows neighboring nMISFETs or neighboring pMISFETs to share sources/drains.

### Embodiment 2

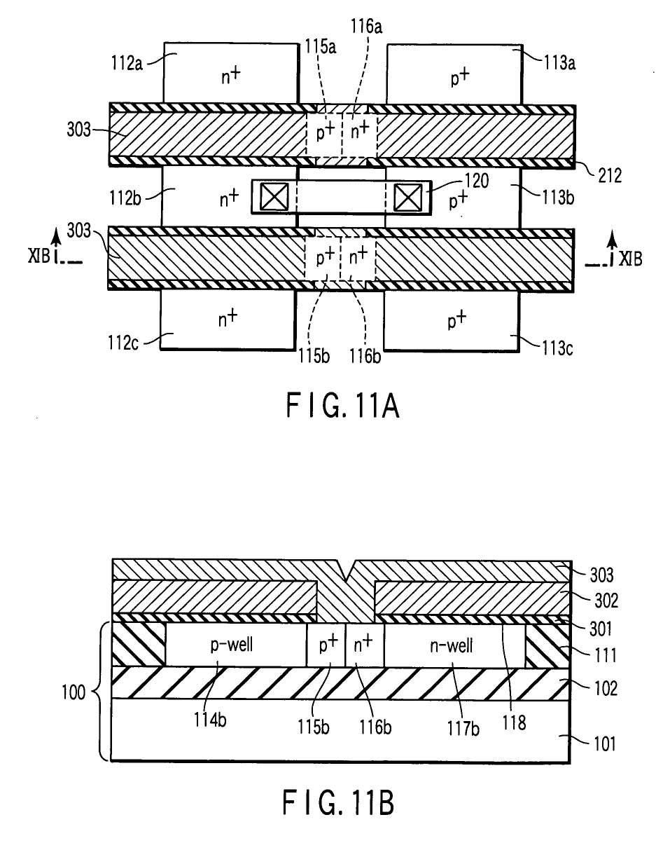

FIGS. 11A and 11B show the structure of a semiconductor device according to a second embodiment of the present invention. FIG. 11A is a plan view and FIG. 11B is a sectional view taken along line XIB-XIB of FIG. 11A. In FIGS. 11A and 11B, corresponding constituents to those in FIGS. 1A and 1B are denoted by like reference numerals and detailed descriptions thereof are omitted.

In this embodiment, stacked films of a poly-Si film 302 and a cobalt silicide film (CoSi₂ film) 303 are used as a gate electrode. The CoSi₂ film 303 is connected to the p⁺ diffusion layer 115 and the n⁺ diffusion layer 116 through contact hole.

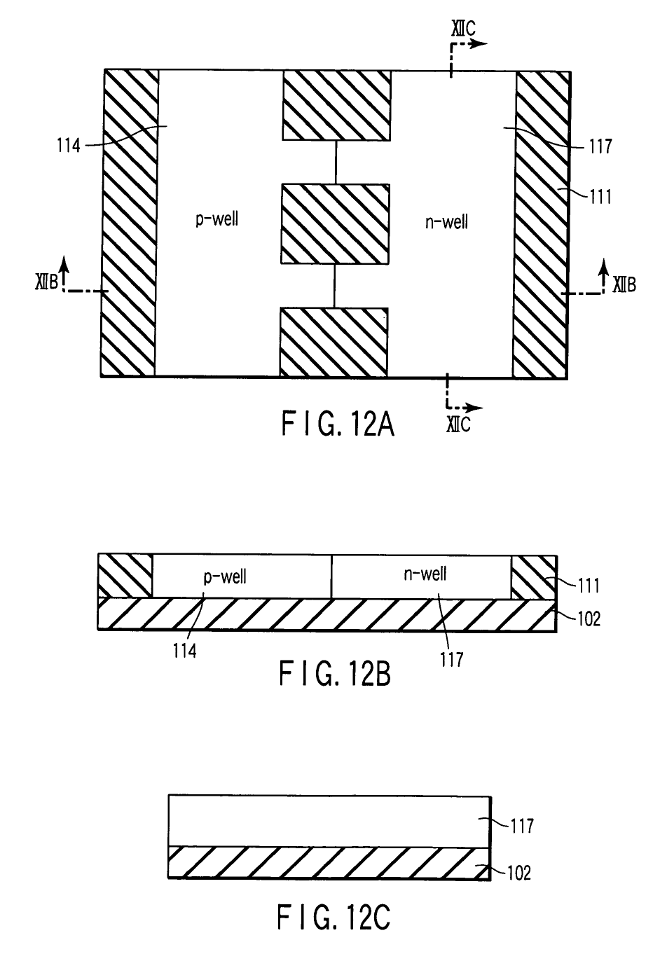

The process of manufacturing the semiconductor device according to this embodiment will be described hereinafter with reference to FIGS. 12A, 12B and 12C to FIGS. 14A, 14B and 14C. Note that, in FIGS. 12A, 12B and 12C to FIGS. 14A, 14B and 14C, the Si support substrate 101 of the SOI substrate 100 is omitted.

First, as shown in FIGS. 12A, 12B and 12C, an SOI substrate 100 is prepared in which the thickness of an Si thin layer on a buried oxide film 102 is of the order of 100 nm. Subsequently, an isolation insulating film 111 the depth of which is of the order of 100 nm is formed by means of STI techniques. This isolation insulating film 111 is formed in regions other than pMISFET and nMISFET formation regions.

After that, an n-type well 117 and a p-type well 114 are formed in the DT-pMISFET formation region and the DT-nMISFET formation region, respectively, in the Si thin layer. In the drawing, a pn junction between the p-type well 114 and the n-type well 117 is formed in two places. A portion of a gate electrode is formed on the pn junction portion at a later time.

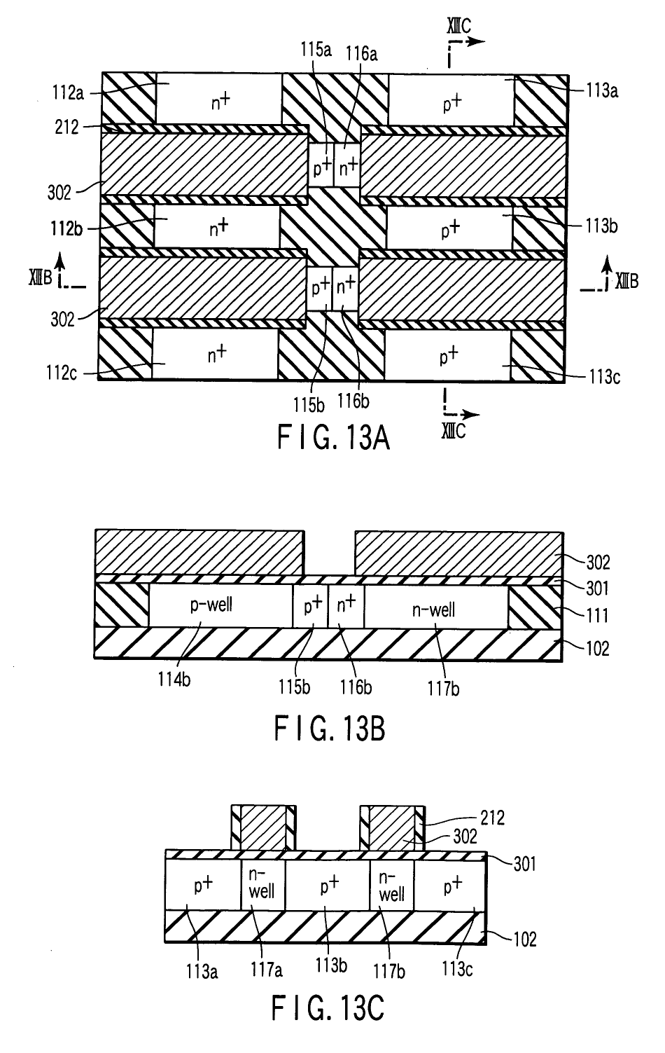

Next, as shown in FIGS. 13A, 13B and 13C, a gate insulating film 301, such as an SiO₂ film, which is of the order of 1.5 nm in thickness is formed on the surface of the p-type well 114 and the n-type well 117. Subsequently, a poly-Si film 302 which is of the order of 150 nm in thickness is deposited on the gate insulating film 301 by means of LPCVD. Further, to form gate electrodes, a resist pattern not shown is formed on the poly-Si film 302. After that, the poly-Si film 302 is etched by RIE.

After the removal of the resist pattern, using the patterned poly-Si film 302 as a mask, p-type impurities and n-type impurities are ion implanted into the DT-pMISFET formation region and the DT-nMISFET formation region, respectively. Thereby, though not shown, shallow p-type and n-type impurity diffusion layers (extension regions) are formed. A resist pattern is formed as a mask in regions into which the impurity ions are not implanted.

Next, a silicon nitride film (Si₃N₄ film) is formed at a thickness of the order of 30 nm. Further, sidewall portions 212 are formed on the sidewalls of the patterned poly-Si film 302 by etching the Si₃N₄ film by means of RIE. Subsequently, using a resist pattern not shown as a mask, the poly-Si film 302 and the sidewall portions 212 are etched away in the regions where contacts to the gate electrodes are formed.

Next, p-type impurities and n-type impurities are ion implanted into the n-type well 117 and the p-type well 114, respectively. At this time, not only the resist pattern but also the poly-Si film 302 and the sidewall portions 212 are used as a mask. By the step of ion implantation of the n-type impurities, n⁺-type source/drain regions 112 (112a, 112b, and 112c) are formed in the p-type well 114. In this ion implantation step, at the same time, the n-type impurities are also ion implanted into end portion (boundary portion between the p-type well 114 and the n-type well 117) of the n-type well 117 to form n⁺ diffusion layers (n⁺-type semiconductor portions) 116 (116a and 116b). Also, p⁺-type source/drain regions 113 (113a, 113b, and 113c) are formed in the n-type well 117 by the step of ion implantation of the p-type impurities. In this ion implantation step, at the same time, the p-type impurities are also ion implanted into end portion (boundary portion between the p-type well 114 and the n-type well 117) of the p-type well 114 to form p⁺ diffusion layers (p⁺-type semiconductor portions) 115 (115a and 115b). The order in which the p-type impurity ion implantation step and the n-type impurity ion implantation step are performed is not particularly restricted. Further, the implanted impurities are activated at a temperature of the order of 1000° C. The p⁺ diffusion layers 115 and the n⁺ diffusion layers 116 are used as contacts to the gate electrodes.

Thus, the n⁺-type source/drain regions 112 and the n⁺ diffusion layers 116 are formed at the same time by the n-type impurity ion implantation step. Also, the p⁺-type source/drain regions 113 and the p⁺ diffusion layers 115 are formed at the same time by the p-type impurity ion implantation step. Therefore, the number of ion implantation steps can be reduced, allowing the manufacturing process to be simplified.

The exemplary ion implantation conditions in forming the n-type extension regions are such that the impurity ions are As ions, the accelerating voltage is 15 keV, and the dose is 3×10¹⁴ cm⁻². The exemplary ion implantation conditions in forming the n⁺-type source/drain regions are such that the impurity ions are As ions, the accelerating voltage is 45 keV, and the dose is 3×10¹⁵ cm⁻².

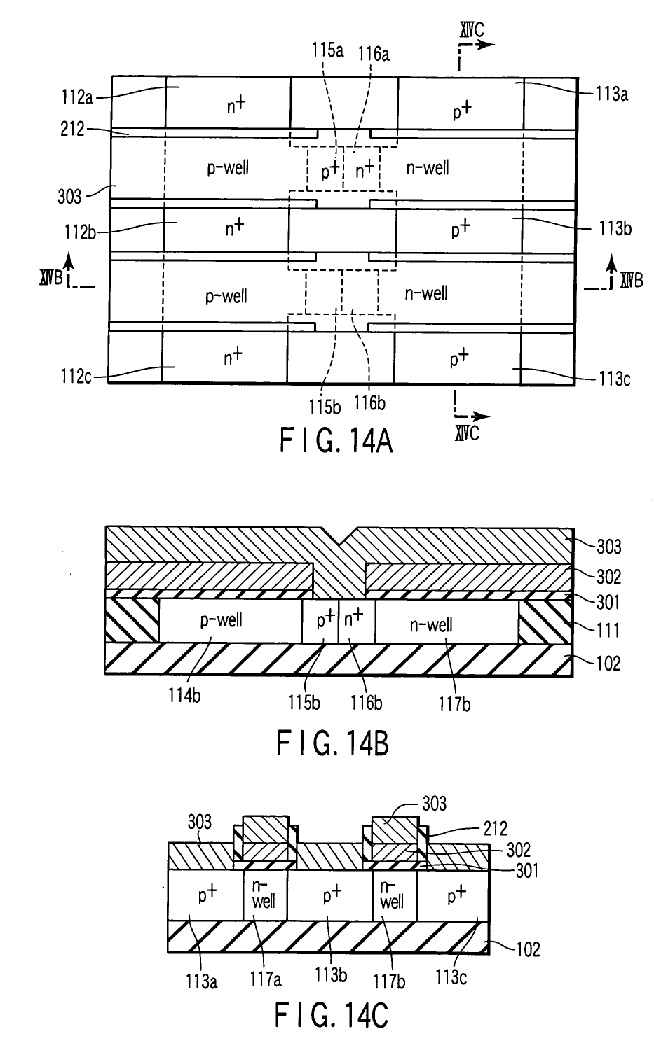

Next, as shown in FIGS. 14A, 14B and 14C, a cobalt film (Co film) is formed over the entire surface and then a heat treatment is carried out. By this heat treatment, a CoSi₂ film 303 is selectively formed on the poly-Si film 302, on the n⁺-type source/drain regions 112 and the p⁺-type source/drain regions 113, and on the p⁺ diffusion layers 115 and the n⁺ diffusion layers 116. The CoSi₂ film 303 is also formed on the sidewalls of the poly-Si film 302 because the sidewall portions 212 are not formed on the sidewalls of the poly-Si film 302 (opposed surfaces of the poly-Si film) in the regions where the p⁺ diffusion layers 115 and the n⁺ diffusion layers 116 have been formed. Therefore, the patterns of the poly-Si film 302 are connected together by the CoSi₂ film 303 through the bridging phenomenon.

In this manner, the gate electrode is obtained which includes of the gate electrode lower portion formed of the poly-Si film 302 and the gate electrode upper portion formed of the CoSi₂ film 303. The p-type semiconductor region and the n-type semiconductor region are electrically connected by the gate electrode upper portion (CoSi₂ film 303).

The subsequent process remains unchanged from the usual LSI manufacturing process. That is, an interlayer insulating film of TEOS-SiO₂ is deposited by means of CVD. Subsequently, contact holes are formed in the interlayer insulating film on the source/drain regions and an the gate electrodes. Further, metal interconnections (for example, Al wirings) are formed in the contact holes and on the interlayer insulating film. At this time, a contact interconnection (connecting portion) 120 is also formed to electrically connect the n⁺ source/drain region 112b of the nMISFET and the p⁺ source/drain region 113b of the pMISFET. Thus, a CMISFET inverter is formed.

As can be seen from the foregoing, this embodiment can also offer the same advantages as the first embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a p-type semiconductor region provided in a semiconductor substrate;
an n-type semiconductor region provided in the semiconductor substrate and being in contact with the p-type semiconductor region;
an n-type source region and an n-type drain region between which the p-type semiconductor region is sandwiched;
a p-type source region and a p-type drain region between which the n-type semiconductor region is sandwiched;
a gate insulating film formed on the p-type semiconductor region and the n-type semiconductor region; and
a gate electrode formed on the gate insulating film and electrically connected to the p-type semiconductor region and the n-type semiconductor region.

2. The semiconductor device according to claim 1, further comprising a connecting portion which electrically connects one of the n-type source region and the n-type drain region and one of the p-type source region and the p-type drain region.

3. The semiconductor device according to claim 2, wherein the other of the n-type source region and the n-type drain region and the other of the p-type source region and the p-type drain region are separated from each other.

4. The semiconductor device according to claim 1, wherein the gate electrode is electrically connected to a boundary portion of the p-type semiconductor region and the n-type semiconductor region.

5. The semiconductor device according to claim 4, wherein the gate insulating film is not formed on the boundary portion.

6. The semiconductor device according to claim 5, wherein the gate electrode has a portion formed on the boundary portion.

7. The semiconductor device according to claim 6, wherein at least that portion of the gate electrode which is formed on the boundary portion is formed of a metallic conductive material.

8. The semiconductor device according to claim 5, wherein the gate electrode includes a lower portion formed on the gate insulating film and an upper portion formed on the lower portion and the boundary portion.

9. The semiconductor device according to claim 4, wherein the p-type semiconductor region has a higher p-type impurity concentration in the boundary portion than in a portion away from the boundary portion and the n-type semiconductor region has a higher n-type impurity concentration in the boundary portion than in a portion away from the boundary portion.

10. The semiconductor device according to claim 1, wherein the semiconductor substrate is an SOI substrate.

11. A method of manufacturing a semiconductor device comprising:
forming a p-type well and an n-type well in a semiconductor substrate which are in contact with each other;
forming a dummy gate on the p-type well and the n-type well except a boundary portion of the p-type well and the n-type well;
introducing n-type impurities into the p-type well using the dummy gate as a mask to form an n-type source region and an n-type drain region in the p-type well;
introducing p-type impurities into the n-type well using the dummy gate as a mask to form a p-type source region and a p-type drain region in the n-type well;
forming a first insulating film which surrounds the dummy gate;
forming a trench in the first insulating film by removing the dummy gate;
forming a gate insulating film in the trench;
removing the first insulating film on the boundary portion to expose a surface of the boundary portion; and
forming a gate electrode on the gate insulating film in the trench and on the exposed surface of the boundary portion.

12. The method according to claim 11, wherein introducing the n-type impurities into the p-type well using the dummy gate as a mask includes introducing n-type impurities into the boundary portion, and introducing the p-type impurities into the n-type well using the dummy gate as a mask includes introducing p-type impurities into the boundary portion.

13. The method according to claim 11, further comprising forming a connecting portion which electrically connects one of the n-type source region and the n-type drain region and one of the p-type source region and the p-type drain region.

14. A method of manufacturing a semiconductor device comprising:
forming a p-type well and an n-type well in a semiconductor substrate which are in contact with each other;
forming a gate insulating film on the p-type well and the n-type well;
forming a lower portion of a gate electrode on the gate insulating film except a boundary portion of the p-type well and the n-type well;
introducing n-type impurities into the p-type well using the lower portion of the gate electrode as a mask to form an n-type source region and an n-type drain region in the p-type well;
introducing p-type impurities into the n-type well using the lower portion of the gate electrode as a mask to form a p-type source region and a p-type drain region in the n-type well; and
forming an upper portion of the gate electrode on the lower portion of the gate electrode and on a surface of the boundary portion.

15. The method according to claim 14, wherein introducing the n-type impurities into the p-type well using the lower portion of the gate electrode as a mask includes introducing n-type impurities into the boundary portion, and introducing the p-type impurities into the n-type well using the lower portion of the gate electrode as a mask includes introducing p-type impurities into the boundary portion.

16. The method according to claim 14, further comprising forming a connecting portion which electrically connects one of the n-type source region and the n-type drain region and one of the p-type source region and the p-type drain region.
